(19) United States
(12) Patent Application Publication
(10) Pub. No.: US 2026/0206437 A1
(43) Pub. Date: Jul. 16, 2026

(54) DISPLAY DEVICE AND ELECTRONIC DEVICE INCLUDING THE SAME

(71) Applicant: Samsung Display Co., LTD., Yongin-si (KR)

(72) Inventors: HYUN SUP LEE, Yongin-si (KR); DAE-YOUNG LEE, Yongin-si (KR)

(21) Appl. No.: 19/371,304

(22) Filed: Oct. 28, 2025

(30) Foreign Application Priority Data
Jan. 15, 2025 (KR) 10-2025-0006170

(51) Int. Cl. H10K 59/131; H10K 59/35

(52) U.S. Cl. CPC H10K 59/131; H10K 59/353

(57) ABSTRACT

A display device includes a substrate and first to third light-emitting elements disposed on the substrate, each being configured to emit light in a different wavelength band. Each of the first to third light-emitting elements includes a first electrode, a light-emitting layer, and a second electrode. The third light-emitting element further includes at least one light-emitting structure layer disposed between the first electrode and the second electrode and including at least one light-emitting layer. The first light-emitting element and the second light-emitting element are electrically connected with a first driving power line configured to supply a first driving power voltage. The third light-emitting element is electrically connected with a second driving power line configured to supply a second driving power voltage. The second driving power voltage may have a value greater than that of the first driving power voltage.

This application claims priority to Korean Patent Application No. 10-2025-0006170, filed on January 15, 2025, and all the benefits accruing therefrom under 35 U.S.C. §119, the content of which is incorporated herein in its entirety by reference.

### BACKGROUND

### Field

The disclosure relates to a display device and an electronic device, and more particularly, to a display device and an electronic device in which power supply wiring applied to each light-emitting element is independently operated to improve device efficiency and enhance reliability.

### Description of the Related Art

An organic light-emitting display device has self-emissive characteristics and a separate light source is not desired, unlike a liquid crystal display device. As a result, the thickness and weight of the device may be reduced. Additionally, organic light-emitting display devices exhibit superior properties such as relatively low power consumption, relatively high luminance, and relatively fast response speed.

Recently, various methods are being studied to improve the efficiency and reliability of display devices.

### SUMMARY

The disclosure aims to provide a display device with improved device efficiency and enhanced reliability.

The disclosure further aims to provide an electronic device with improved device efficiency and enhanced reliability.

A display device in an embodiment of the disclosure includes a substrate and first to third light-emitting elements disposed on the substrate, each being configured to emit light in a different wavelength band. Each of the first to third light-emitting elements includes a first electrode, a light-emitting layer, and a second electrode. The third light-emitting element includes at least one light-emitting structure layer, which is disposed between the first electrode and the second electrode and includes at least one light-emitting layer. The first light-emitting element and the second light-emitting element are electrically connected to a first driving power line configured to supply a first driving power voltage. The third light-emitting element is electrically connected to a second driving power line configured to supply a second driving power voltage. The second driving power voltage has a different value from that of the first driving power voltage.

In an embodiment, the value of the second driving power voltage may be greater than that of the first driving power voltage.

In an embodiment, the first driving power line and the second driving power line may be electrically insulated from each other.

In an embodiment, the display device may further include a fourth light-emitting element configured to emit light in a wavelength band substantially the same as that of the second light-emitting element. The fourth light-emitting element may be electrically connected to the first driving power line.

In an embodiment, the first to fourth light-emitting elements may each be provided in plural. The first and third light-emitting elements may be alternately arranged along a first direction. The second and fourth light-emitting elements may be alternately arranged along the first direction.

In an embodiment, the first and third light-emitting elements may be alternately arranged along a second direction intersecting the first direction. The second light-emitting elements may be successively arranged along the second direction. The fourth light-emitting elements may be successively arranged along the second direction.

In an embodiment, a first data line configured to transfer a first data signal may be electrically connected to the second and third light-emitting elements. A second data line next (adjacent) to the first data line and configured to transfer a second data signal may be electrically connected to the first and fourth light-emitting elements.

In an embodiment, the first to fourth light-emitting elements may each be provided in plural. The first to fourth light-emitting elements may form a unit pixel group. The unit pixel group may be repeatedly arranged along the first direction. The first and second data lines may extend along the first direction. The first data line may be alternately electrically connected to the second and third light-emitting elements along the first direction. The second data line may be alternately electrically connected to the first and fourth light-emitting elements along the second direction.

In an embodiment, the first driving power line may include a first stem part extending along the first direction and a first branch part extending from the first stem part. The second driving power line may include a second stem part extending along the first direction and a second branch part extending from the second stem part. The first and second branch parts may be arranged side by side along the second direction intersecting the first direction. The first driving power line may be electrically connected to the first, second, and fourth light-emitting elements through the second branch part. The second driving power line may be electrically connected to the third light-emitting element through the first branch part.

In an embodiment, the first driving power line may include a first stem part extending along a first direction and a first branch part extending from the first stem part. The second driving power line may include a second stem part extending along the first direction and a second branch part extending from the second stem part. The first and second branch parts may be arranged side by side along the second direction intersecting the first direction. The first driving power line may be electrically connected to the first, second, and fourth light-emitting elements through the first branch part. The second driving power line may be electrically connected to the third light-emitting element through the second branch part.

In an embodiment, the first branch part may include a first sub-branch part extending from one side of the first stem part in the second direction and a second sub-branch part extending from the opposite side of the second stem part in the second direction. The first driving power line may be electrically connected to the first and second light-emitting elements through the first sub-branch part. The first driving power line may be electrically connected to the fourth light-emitting element through the second sub-branch part.

In an embodiment, the second driving power line may be electrically connected to the third light-emitting element through the second branch part. In an embodiment, the first branch part may include a first sub-branch part and a second sub-branch part. The first and second sub-branch parts may form a row in the second direction. The first and second sub-branch parts may be each provided in plural. The first sub-branch part may be disposed on one side of the first stem part in the second direction in a first row. The second sub-branch part may be disposed on the opposite side of the first stem part in the second direction in the first row. The first sub-branch part may be disposed on the opposite side of the first stem part in the second direction in a second row. The second sub-branch part may be disposed on the one side of the first stem part in the second direction in the second row.

In an embodiment, the second branch part may extend from one side of the second stem part in the second direction. The second branch part may be disposed relatively closer to the fist sub-branch part than to the second sub-branch part.

In an embodiment, the first and second stem parts may have substantially a same width in the second direction.

In an embodiment, the first and second driving power lines may each be provided in plural. The first and second driving power lines may each extend along the first direction. The first and second driving power lines may be alternately arranged along the second direction intersecting the first direction.

In an embodiment, the first driving power lines may be electrically connected to each other. The second driving power lines may be electrically connected to each other.

A display device in another embodiment of the disclosure includes a substrate and first to fourth light-emitting elements arranged on the substrate. The first, second, and third light-emitting elements each emit light in different wavelength bands. The second and fourth light-emitting elements emit light in substantially a same wavelength band. Each of the first to fourth light-emitting elements includes a first electrode, a light-emitting layer, and a second electrode. The third light-emitting element further includes at least one light-emitting structure layer disposed between the first and second electrodes and including at least one light-emitting layer. The first, second, and fourth light-emitting elements are electrically connected to a first driving power line configured to supply a first driving power voltage. The third light-emitting element is electrically connected to a second driving power line configured to supply a second driving power voltage. A first data line configured to transfer a first data signal is electrically connected to the second and third light-emitting elements. A second data line next (adjacent) to the first data line and configured to transfer a second data signal is electrically connected to the first and fourth light-emitting elements.

In an embodiment, the first and second driving power lines may be electrically insulated from each other. The second driving power voltage may have a value higher than that of the first driving power voltage.

In an embodiment, the first and second driving power lines may each be provided in plural. The first and second driving power lines may each extend along a first direction. The first and second driving power lines may be alternately arranged along a second direction intersecting the first direction.

An electronic device in an embodiment of the disclosure includes a substrate and first to third light-emitting elements arranged on the substrate, each being configured to emit light in a different wavelength band. Each of the first to third light-emitting elements includes a first electrode, a light-emitting layer, and a second electrode. The third light-emitting element further includes at least one light-emitting structure layer disposed between the first and second electrodes and including at least one light-emitting layer. The first and second light-emitting elements are electrically connected to a first driving power line configured to supply a first driving power voltage. The third light-emitting element is electrically connected to a second driving power line configured to supply a second driving power voltage. The second driving power voltage has a value different from that of the first driving power voltage.

In an embodiment, the value of the second driving power voltage may be greater than that of the first driving power voltage.

By embodiments of the disclosure, it is possible to provide a display device and an electronic device with an improved device efficiency and enhanced reliability, by independently connecting the power supply wiring that supplies the driving voltage to each light-emitting element of the display device.

### BRIEF DESCRIPTION OF THE DRAWINGS

These and/or other features will become apparent and more readily appreciated from the following description of the embodiments, taken in conjunction with the accompanying drawings in which:

FIG. 1 is a schematic plan view of an embodiment of a display device DD according to the disclosure;

FIG. 2 is an exemplary equivalent circuit diagram of the pixels shown in FIG. 1;

FIG. 3 is a plan view illustrating a section marked with AA in FIG. 1;

FIG. 4 is a cross-sectional view of an embodiment of a pixel according to the disclosure;

FIG. 5 is a schematic cross-sectional view of a portion of the display device;

FIG. 6 is a plan view of a portion of the display device;

FIG. 7 is a schematic plan view showing a part of the display device;

FIG. 8 is a schematic plan view showing a part of the display device;

FIG. 9 is a schematic plan view showing a part of the display device;

FIG. 10 is a schematic plan view showing a part of the display device;

FIG. 11 is a schematic plan view showing a part of the display device;

FIG. 12 is a schematic plan view showing a part of the display device;

FIG. 13 is a schematic diagram illustrating electrical connections of pixels;

FIG. 14 is a schematic diagram illustrating electrical connections of pixels;

FIG. 15 is a block diagram of an embodiment of an electronic device according to the disclosure; and

FIG. 16 illustrates embodiments of electronic devices according to the disclosure.

### DETAILED DESCRIPTION

References will now be made in detail to embodiments, of which illustrative embodiments are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are merely described below, by referring to the drawing figures, to explain features of the disclosure.

When an element (or region, layer, portion, etc.) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the disclosure shall not be restricted to the thicknesses, ratios, dimensions, etc. illustrated in the drawings.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the disclosure. Unless clearly used otherwise, any expressions in a singular form may include a meaning of a plural form. The term “and/or” shall include the combination of a plurality of listed items or any of the plurality of listed items.

Moreover, relative terms, such as “below,” “under,” “beneath,” “lower,” “bottom,” “above,” “over,” “upper,” “top,” etc., may be used herein to describe one element’s relationship to another element as illustrated in the accompanying drawing figures. It shall be understood that relative terms are intended to encompass different orientations of the device in addition to the orientation depicted in the accompanying drawing figures. For example, if the device in one of the drawing figures is turned over, elements described as being on the “lower” side of the other elements would then be oriented on “upper” sides of the other elements. The exemplary term “lower” may therefore encompass an orientation of both “lower” and “upper,” depending on the particular orientation of the figure. Similarly, if the device in one of the drawing figures is turned over, elements described as “below” or “beneath” other elements would then be oriented “above” the other elements. The exemplary term “below” or “beneath” may therefore encompass an orientation of both above and below.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the disclosure pertains. Any term that is defined in a general dictionary shall be construed to have the same meaning in the context of the relevant art, and, unless otherwise defined explicitly, shall not be interpreted to have an idealistic or excessively formalistic meaning.

In the specification, when a particular process sequence may be implemented differently, the described sequence of processes may be performed in a different order. For example, two sequentially described processes may be performed substantially simultaneously, or the order of description may be reversed.

In the description below, first to third directions DR1 - DR3 are defined in order to describe a display device in accordance with illustrative embodiments of the disclosure. The display device may be formed to include pixels in a plan view defined by the first direction DR1 and the second direction DR2. The third direction DR3 may be defined as the thickness direction of the display device, and the first to third directions DR1 - DR3 may be mutually orthogonal or intersecting.

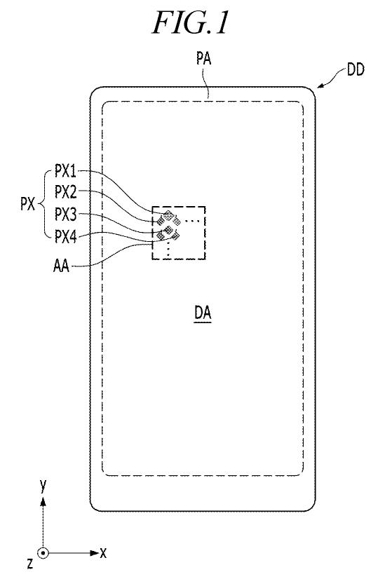

FIG. 1 is a schematic plan view of an embodiment of a display device DD according to the disclosure. Referring to FIG. 1, the display device DD may include a display area DA and a peripheral area PA outside the display area DA.

The display area DA, which is a portion where an image is displayed, may have a plurality of pixels arranged therein. The display area DA may have various shapes, such as circular, elliptical, polygonal, or a predetermined geometric shape. In FIG. 1, in an embodiment, the display area DA is illustrated as having a generally quadrangular shape, e.g., rectangular shape with rounded corners.

The peripheral area PA may be disposed outside the display area DA. The peripheral area PA may be disposed to surround at least a part of the display area DA. The peripheral area PA may be a region where light-emitting element (e.g., light-emitting diodes) are not arranged.

Hereinafter, an organic light-emitting display device will be described in an embodiment of the display device DD according to the disclosure. However, the display device of the disclosure is not limited thereto. In another embodiment, the display device DD may be an inorganic light-emitting display device or a quantum dot light-emitting display device. In an embodiment, the light-emitting layer of the display element included in the display device DD may include an organic material, an inorganic material, quantum dots, a combination of an organic material and quantum dots, or a combination of an inorganic material and quantum dots, for example.

In an embodiment of the disclosure, pixels PX may include first to fourth pixels PX1, PX2, PX3, and PX4.

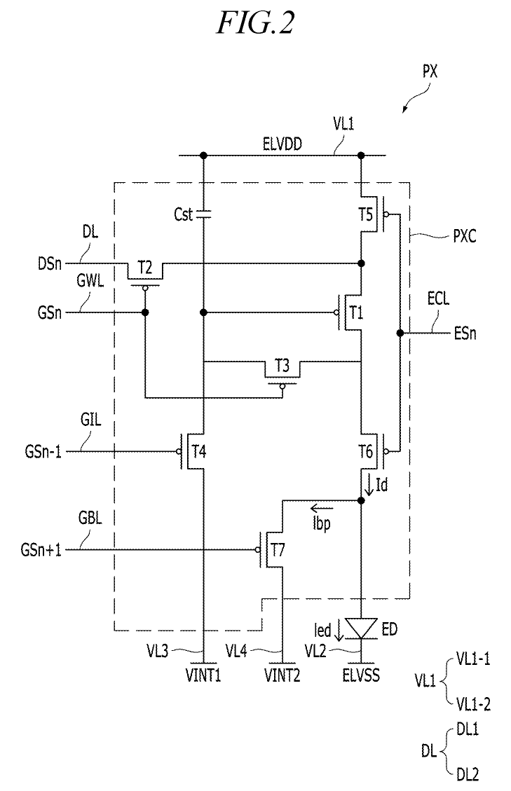

FIG. 2 is an exemplary equivalent circuit diagram of the pixels shown in FIG. 1. Referring to FIG. 2, a pixel PX is electrically connected to a data line DL, gate lines GWL, GIL, GBL (hereinafter referred to as first gate line GIL, second gate line GWL, and third gate line GBL), and emission control lines ECL.

The pixel PX may receive a first voltage ELVDD, a second voltage ELVSS, a first initialization voltage VINT1, and a second initialization voltage VINT2. The first voltage ELVDD may be supplied to a light-emitting element (e.g., light-emitting diode ED) through a first power line VL1. Although not illustrated, the first voltage ELVDD, the second voltage ELVSS, the first initialization voltage VINT1, and the second initialization voltage VINT2 may be provided using voltages generated by a power management circuit of the display device DD, for example.

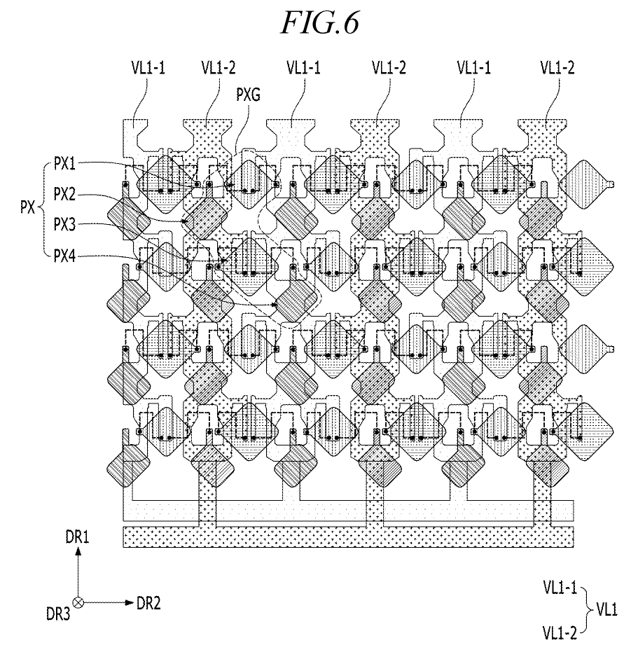

In an embodiment of the disclosure, the first power line VL1 may include a first driving power line VL1-1 configured to apply a first power voltage and a second driving power line VL1-2 configured to apply a second power voltage, as described later with reference to FIG. 6. One pixel may be electrically connected to either the first driving power line VL1-1 or the second driving power line VL1-2. In an embodiment, the first power line VL1 connected to a first pixel PX1 may be the first driving power line VL1-1 among the first driving power line VL1-1 and the second driving power line VL1-2. The first voltage ELVDD described with reference to FIG. 2 may refer to either the first driving voltage or the second driving voltage, and the first power line VL1 may refer to either the first driving power line or the second driving power line. Further details regarding the first voltage ELVDD supplied to the pixel PX and the first power line VL1 will be described later, for example.

The pixel PX may include a pixel circuit section PXC and a light-emitting diode ED. The pixel circuit section PXC may include first to seventh transistors T1 - T7 and a capacitor Cst. Each of the first to seventh transistors T1 - T7 may be a P-type transistor having a low-temperature polycrystalline silicon (“LTPS”) semiconductor layer; however, the transistors are not limited thereto and may be N-type transistors having an oxide semiconductor as the semiconductor layer. Additionally, unlike FIG. 2, at least one of the first to seventh transistors T1 - T7 may be an N-type transistor, while the remaining transistors may be P-type transistors. The circuit configuration and the number of transistors in the pixel PX according to the disclosure are merely illustrative and are not limited to those shown in FIG. 2, and the configuration of the pixel circuit section PXC may be modified.

A first transistor T1 may supply a driving current Id to the light-emitting diode ED based on the magnitude of a data signal DSn. In this regard, the first transistor T1 may be also referred to as a driving transistor Tdr, as will be described later with reference to FIG. 4. Second to seventh transistors T2 - T7 may turn on or off to allow the first transistor T1 to receive the data signal DSn and supply the driving current Id based on the magnitude of the data signal DSn. To this end, gate electrodes of the second to seventh transistors T2 - T7 may be connected to any of the first gate line GIL, the second gate line GWL, the third gate line GBL, and the emission control lines ECL. In this regard, at least one of the second to seventh transistors T2 - T7 may be also referred to as a switch transistor Tsw, as will be described later with reference to FIG. 4.

The first transistor T1 may include a first electrode connected to the first power line VL1 via a fifth transistor T5, a second electrode electrically connected to an anode of the light-emitting diode ED via a sixth transistor T6, and a gate electrode connected to one end of the capacitor Cst. The first transistor T1 may receive the data signal DSn transferred by the data line DL based on a switching operation of a second transistor T2 and supply the driving current Id to the light-emitting diode ED.

The second transistor T2 may include a first electrode connected to the data line DL, a second electrode connected to the first electrode of the first transistor T1, and a gate electrode connected to the second gate line GWL. The second transistor T2 may turn on in response to a gate signal GSn (hereinafter referred to as a second gate signal) transferred via the second gate line GWL and transfer the data signal DSn received from the data line DL to the first electrode of the first transistor T1. Here, n is a natural number.

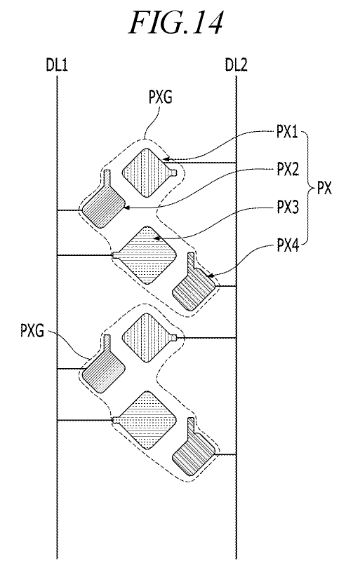

In an embodiment of the disclosure, the data line DL may be constituted with a first data line DL1 configured to transfer a first data signal and a second data line DL2 configured to transfer a second data signal, as described later with reference to FIG. 14. One pixel PX may be connected with either the first data line DL1 or the second data line DL2. The data line DL described with reference to FIG. 2 may refer to either the first data line DL1 or the second data line DL2.

A third transistor T3 may include a first electrode connected with the gate electrode of the first transistor T1, a second electrode connected with the second electrode of the first transistor T1, and a gate electrode connected with the second gate line GWL. The third transistor T3 may turn on in response to the second gate signal GSn transferred via the second gate line GWL and connect the gate electrode and the second electrode of the first transistor T1 with each other to form a diode connection.

A fourth transistor T4 may include a first electrode connected with the gate electrode of the first transistor T1, a second electrode connected with a third power line VL3 that supplies the first initialization voltage VINT1, and a gate electrode connected with the first gate line GIL. The fourth transistor T4 may turn on in response to a gate signal GSn-1 (hereinafter referred to as a first gate signal) transferred via the first gate line GIL and perform an initialization operation of initializing the voltage of the gate electrode of the first transistor T1 by supplying the first initialization voltage VINT1 to the gate electrode of the first transistor T1.

A fifth transistor T5 may include a first electrode connected with the first power line VL1, a second electrode connected with the first electrode of the first transistor T1, and a gate electrode connected with an emission control line ECL. A sixth transistor T6 may include a first electrode connected with the second electrode of the first transistor T1, a second electrode connected to the anode of the light-emitting diode ED, and a gate electrode connected to the emission control line ECL. The fifth transistor T5 and the sixth transistor T6 may turn on simultaneously in response to an emission control signal ESn transferred via the emission control line ECL. The first voltage ELVDD supplied through the turned-on fifth transistor T5 may be compensated through the first transistor T1 and delivered to the light-emitting diode ED.

A seventh transistor T7 may include a first electrode connected with a fourth power line VL4 that supplies a second initialization voltage VINT2, a second electrode connected with the second electrode of the sixth transistor T6, and a gate electrode connected with the third gate line GBL. The seventh transistor T7 may turn on in response to a gate signal GSn+1 (hereinafter referred to as a third gate signal) transferred via the third gate line GBL. The second initialization voltage VINT2 supplied through the turned-on seventh transistor T7 may initialize the anode of the light-emitting diode ED.

One end of the capacitor Cst may be connected with the gate electrode of the first transistor T1, as described above, while an opposite end may be connected with the first power line VL1. A cathode of the light-emitting diode ED may be connected with a second power line VL2 configured to supply the second voltage ELVSS.

The light-emitting diode ED may include a light-emitting diode. The light-emitting diode may include a light-emitting material such as an organic light-emitting material, an inorganic light-emitting material, quantum dots, or quantum rods. The light-emitting diode ED may emit light based on an emission current Ied.

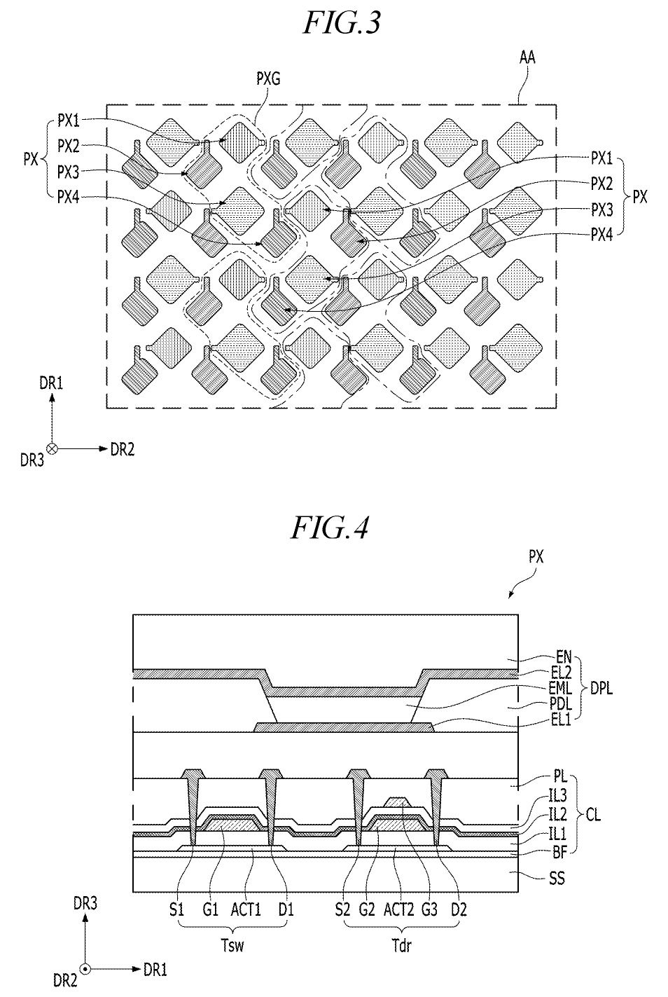

FIG. 3 is a plan view illustrating a section marked with AA in FIG. 1. For convenience of description, lower-layer components are omitted in FIG. 3, and pixels PX are only shown.

Referring to FIG. 3, the pixels PX may include first to fourth pixels PX1, PX2, PX3, and PX4. In an embodiment of the disclosure, as illustrated in FIG. 3, the first to fourth pixels PX1, PX2, PX3, and PX4 may form a unit pixel group PXG. The unit pixel group PXG may be repeatedly arranged along a first direction DR1. The unit pixel group PXG may be a group defined for convenience of description.

In an embodiment, the first pixel PX1, the second pixel PX2, and the third pixel PX3 may emit light in different wavelength bands. In an embodiment, the first pixel PX1 may emit light in a first wavelength band corresponding to red, the second pixel PX2 may emit light in a second wavelength band corresponding to green, and the third pixel PX3 may emit light in a third wavelength band corresponding to blue, for example.

In an embodiment, the fourth pixel PX4 may emit light in a second wavelength band that is substantially the same as that of the second pixel PX2. However, the disclosure is not limited thereto, and the fourth pixel PX4 may emit light in a wavelength band that is substantially the same as at least one of the first pixel PX1, the second pixel PX2, and the third pixel PX3. In an alternative embodiment, the fourth pixel PX4 may emit light in a wavelength band different from those of the first to third pixels PX1, PX2, and PX3.

In an embodiment, the first pixel PX1 and the third pixel PX3 may be alternately arranged along the first direction DR1. Likewise, the second pixel PX2 and the fourth pixel PX4 may be alternately arranged along the first direction DR1.

In an embodiment, the first pixel PX1 and the third pixel PX3 may be alternately arranged along a second direction DR2. In such a case, the second pixel PX2 may be successively arranged along the second direction DR2, and the fourth pixel PX4 may be successively arranged along the second direction DR2.

FIG. 4 is a cross-sectional view of an embodiment of a pixel according to the disclosure. Referring to FIG. 4, a pixel PX may include a substrate SS, a circuit layer CL, and a display layer DPL. For convenience of description, the cross-sectional view of a pixel PX is illustrated, but as shown in FIG. 3, pixels PX may be two-dimensionally arranged, and the structure shown in FIG. 4 may be repeated in the first direction DR1. Furthermore, it shall be appreciated that the cross-sectional view of the pixel PX is simplified for convenience of description.

The substrate SS may include or consist of various materials such as glass, metal, or plastic. In an embodiment, the substrate SS may be a flexible substrate.

The circuit layer CL may be disposed on the substrate SS. The circuit layer CL may correspond to the pixel circuit section PXC shown in FIG. 2. The circuit layer CL may include a buffer layer BF, a semiconductor layer including a first active pattern ACT1 and a second active pattern ACT2, a first insulating layer IL1, a first conductive layer including a first gate pattern G1 and a second gate pattern G2, a second insulating layer IL2, a second conductive layer including a third gate pattern G3, a third insulating layer IL3, a third conductive layer including a first input pattern S1, a first output pattern D1, a second input pattern S2, and a second output pattern D2, and a planarization layer PL.

The circuit layer CL may form a switch transistor Tsw and a driving transistor Tdr based on the layered structure shown in FIG. 4. The driving transistor Tdr may correspond to the first transistor T1 shown in FIG. 2, and the switch transistor Tsw may correspond to any one of the second to seventh transistors T2 - T7 shown in FIG. 2. For convenience of description, only one switch transistor Tsw and one driving transistor Tdr are illustrated in the cross-sectional view of FIG. 4, but it shall be appreciated that this is merely one of embodiments. The number of switch transistors Tsw and driving transistors Tdr appear in a cross-section defined by the first direction DR1 and the third direction DR3 is not limited.

The buffer layer BF may be disposed on the substrate SS. The buffer layer BF may prevent impurity ions from diffusing into an upper surface of the substrate SS, prevent moisture or external air from penetration, and provide a smooth, flat surface. In an embodiment, the buffer layer BF may include or consist of an inorganic material, such as silicon oxide, silicon nitride, aluminum oxide, aluminum nitride, titanium oxide, or titanium nitride, an organic material, such as polyimide, polyester, or acrylic, or a laminated structure thereof.

The semiconductor layer including the first active pattern ACT1 and the second active pattern ACT2 may be disposed on the substrate SS and the buffer layer BF. In an embodiment, used for the semiconductor layer may be an inorganic semiconductor such as amorphous silicon or polysilicon, or an organic semiconductor. The first active pattern ACT1 may provide a signal input/output channel for the switch transistor Tsw, and the second active pattern ACT2 may provide a signal input/output channel for the driving transistor Tdr.

The first insulating layer IL1 may be disposed on and cover the first active pattern ACT1 and the second active pattern ACT2. In an embodiment, the first insulating layer IL1 may include or consist of, but not limited to, a laminate including silicon oxide. The first insulating layer IL1 may function as a gate insulator of the switch transistor Tsw and the driving transistor Tdr.

The first conductive layer including the first gate pattern G1 and the second gate pattern G2 may be disposed on the first insulating layer IL1. The first gate pattern G1 may be disposed to overlap the first active pattern ACT1, and the second gate pattern G2 may be disposed to overlap the second active pattern ACT2. The first gate pattern G1 may serve as a gate electrode of the switch transistor Tsw, and the second gate pattern G2 may serve as a gate electrode of the driving transistor Tdr. The first conductive layer may further include gate lines and emission control lines.

The display device DD may be electrically connected to a gate driving circuit (not shown) through the gate lines and may be electrically connected to an emission driving circuit (not shown) through the emission control lines. The gate lines (not shown) or the emission control lines (not shown) may be electrically connected to the first gate pattern G1 of the switch transistor Tsw corresponding to any of the second to seventh transistors T2 - T7 shown in FIG. 2.

The second insulating layer IL2 may be disposed on and cover the first conductive layer including the first gate pattern G1 and the second gate pattern G2. In an embodiment, the second insulating layer IL2 may include or consist of, but not limited to, a laminate including silicon oxide or silicon nitride. The second insulating layer IL2 may function as a dielectric of the capacitor Cst described with reference to FIG. 2.

The second conductive layer including the second gate pattern G2 may be disposed on the second insulating layer IL2. The second gate pattern G2 may be disposed to overlap the first gate pattern G1. The first gate pattern G1 and the second gate pattern G2 may function as the capacitor Cst described with reference to FIG. 2. As the capacitor Cst is formed to overlap a region corresponding to the driving transistor Tdr, it becomes possible to make the pixel PX smaller and more integrated and to increase the resolution of the display device DD. However, the disclosure is not limited thereto, and the second gate pattern G2 may not be disposed to overlap the region corresponding to the driving transistor Tdr.

The third insulating layer IL3 may be disposed on and cover the second conductive layer including the second insulating layer IL2 and the second gate pattern G2. In an embodiment, the third insulating layer IL3 may include or consist of, but not limited to, a laminate including silicon oxide or silicon nitride. Contact holes may be formed in the third insulating layer IL3 for the formation of the first input pattern S1, the first output pattern D1, the second input pattern S2, and the second output pattern D2.

The third conductive layer including the first input pattern S1, the first output pattern D1, the second input pattern S2, and the second output pattern D2 may be disposed on the third insulating layer IL3 and may contact the semiconductor layer through the above-described contact holes. The first input pattern S1 and the first output pattern D1 may contact the first active pattern ACT1 through the first to third insulating layers IL1, IL2, IL3. The second input pattern S2 and the second output pattern D2 may contact the second active pattern ACT2 through the first to third insulating layers IL1, IL2, IL3. The first input pattern S1 may serve as an input electrode of the switch transistor Tsw, the first output pattern D1 may serve as an output electrode of the switch transistor Tsw, the second input pattern S2 may serve as an input electrode of the driving transistor Tdr, and the second output pattern D2 may serve as an output electrode of the driving transistor Tdr.

Any one of the first to third conductive layers may further include the first power line VL1 shown in FIG. 2. However, the disclosure is not limited thereto, and the circuit layer CL of the display device in an embodiment of the disclosure may further include a fourth conductive layer disposed in a different layer than the first to third conductive layers. The fourth conductive layer may include the first power line VL1 shown in FIG. 2.

Any one of the first to third conductive layers may further include the data line DL shown in FIG. 2. However, the disclosure is not limited thereto, and the circuit layer CL of the display device in an embodiment of the disclosure may further include a fourth conductive layer disposed in a different layer than the first to third conductive layers. The fourth conductive layer may include the data line DL shown in FIG. 2.

In an embodiment, the first power line VL1 may be electrically connected to the third gate pattern G3. The first power line VL1 may be disposed physically closer to the second input pattern S2, which receives a driving current, than to the second output pattern D2, which outputs the driving current.

The planarization layer PL may provide a flat upper surface so that the display layer DPL may be uniformly formed. The planarization layer PL may be formed as a single layer or multiple layers of a film including or consisting of an organic material or an inorganic material. Although not illustrated, a contact hole may be formed in the planarization layer PL for electrical connection with the third conductive layer. A contact pattern formed in the contact hole may transfer a driving current supplied from the circuit layer CL to the display layer DPL. The contact pattern may be disposed physically closer to the second output pattern D2, which outputs the driving current, than to the second input pattern S2, which receives the driving current.

The display layer DPL may be disposed on the circuit layer CL. The display layer DPL may correspond to the light-emitting diode ED shown in FIG. 2. The display layer DPL may include a first electrode EL1, a pixel defining layer PDL, a light-emitting layer EML, a second electrode EL2, and an encapsulation layer EN. It shall be appreciated that the configuration of the display layer DPL is simplified for convenience of description.

The first electrode EL1 may be disposed on the planarization layer PL. The first electrode EL1 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). The first electrode EL1 may serve as an anode electrode of the light-emitting diode ED.

The pixel defining layer PDL may be disposed on the first electrode EL1 and the planarization layer PL. An opening may be defined in the pixel defining layer PDL, and at least a portion of the first electrode EL1 may be exposed through the opening. The pixel defining layer PDL may define an area corresponding to a pixel through the opening. Within the display panel, the pixel defining layer PDL may define a non-emission region overlapping the pixel defining layer PDL and an emission region exposed through the opening.

The light-emitting layer EML may be disposed on the first electrode EL1 and the pixel defining layer PDL. The light-emitting layer EML may include a light-emitting material. In an embodiment, the light-emitting layer EML may include an organic material including or consisting of a fluorescent or phosphorescent material that emits red, green, or blue light. The light-emitting layer EML may include a low-molecular-weight organic material or a high-molecular-weight organic material. Although not illustrated, the display layer DPL may further include a hole control layer, such as a hole transport layer (“HTL”) or a hole injection layer (“HIL”), between the light-emitting layer EML and the first electrode EL1. Additionally, although not illustrated, the display layer DPL may further include an electron control layer, such as an electron transport layer (“ETL”) or an electron injection layer (“EIL”), between the light-emitting layer EML and the second electrode EL2.

The second electrode EL2 may be disposed on the light-emitting layer EML and the pixel defining layer PDL. The second electrode EL2 may be commonly disposed over a plurality of pixels PX. The second electrode EL2 may be a transparent electrode or a reflective electrode. In an alternative embodiment, the second electrode EL2 may be a transparent or semi-transparent electrode. The second electrode EL2 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). The second electrode EL2 may serve as a cathode electrode of the light-emitting diode ED.

The encapsulation layer EN may be disposed on the second electrode EL2. The encapsulation layer EN may include at least one inorganic encapsulation layer and at least one organic encapsulation layer. The encapsulation layer EN may protect the display layer DPL from external moisture or contaminants.

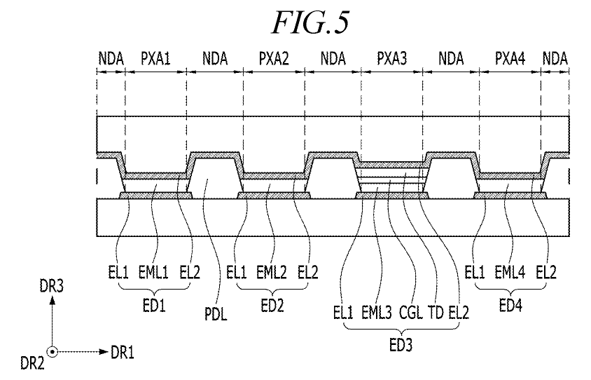

FIG. 5 is a schematic cross-sectional view illustrating a portion of the display device. FIG. 5 shows first to fourth light-emitting elements (e.g., first to fourth light-emitting diodes ED1, ED2, ED3, and ED4), each included in first to fourth pixels PX1, PX2, PX3, and PX4 shown in FIG. 3. In the description below, any corresponding components will be omitted from the description, for convenience of description.

Referring to FIG. 5, the display device DD in an embodiment of the disclosure may include the first to fourth light-emitting diodes ED1, ED2, ED3, and ED4. The first to fourth light-emitting diodes ED1, ED2, ED3, and ED4 may respectively correspond to the first to fourth pixels PX1, PX2, PX3, and PX4 illustrated in FIG. 3. In an embodiment, the first light-emitting diode ED1 may emit light in a first wavelength band through a first pixel region PXA1, for example. The first pixel region PXA1 may an area corresponding the first pixel PX1 in a planar view. Similarly, the second light-emitting diode ED2 may emit light in a second wavelength band through a second pixel region PXA2. The second pixel region PXA2 may be an area corresponding to the second pixel PX2 in a planar view. The third light-emitting diode ED3 may emit light in a third wavelength band through a third pixel region PXA3. The third pixel region PXA3 may be an area corresponding to the third pixel PX3 in a planar view.

In an embodiment of the disclosure, the fourth light-emitting diode ED4 may emit light in the second wavelength band that is substantially the same as the light emitted by the second light-emitting diode ED2 through a fourth pixel region PXA4. The fourth pixel region PXA4 may be an area corresponding to the fourth pixel PX4 in a planar view.

However, the disclosure is not limited thereto, and in another embodiment, the fourth light-emitting diode ED4 may emit light in a wavelength band that is substantially the same as at least one of the first light-emitting diode ED1, the second light-emitting diode ED2, and the third light-emitting diode ED3. In another embodiment, the fourth light-emitting diode ED4 may emit light in a wavelength band different from the wavelength bands emitted by the first to third pixels PX1, PX2, and PX3.

In an embodiment, the third light-emitting diode ED3 may further include a light-emitting structure layer TD disposed between the first electrode EL1 and the second electrode EL2. The light-emitting structure layer TD may include at least one light-emitting layer. A charge generation layer CGL may be disposed between the light-emitting layer EML3 and the light-emitting structure layer TD. Although it is illustrated in FIG. 5 that the third light-emitting diode ED3 includes a single light-emitting structure layer TD, the disclosure is not limited thereto. In another embodiment, the third light-emitting diode ED3 may include multiple light-emitting structure layers and charge generation layers disposed between the first electrode EL1 and the second electrode EL2. Each light-emitting structure layer may include a hole functional layer (not shown) and an electron functional layer (not shown). That is, the third light-emitting diode ED3 may have a tandem structure.

In an embodiment of the disclosure, the third light-emitting diode ED3 may have a tandem structure that includes multiple light-emitting layers and may have higher luminous efficiency than remaining (the other) light-emitting diodes ED1, ED2, and ED4. In such a case, the third light-emitting diode ED3 may desire a higher driving voltage than remaining (the other) light-emitting diodes ED1, ED2, and ED4. In an embodiment, the light-emitting diodes ED1, ED2 and ED4 may respectively include light-emitting layers EML1, EML2 and EML4.

In an embodiment of the disclosure, a first driving power voltage ELVDD1 may be applied to the first light-emitting diode ED1, the second light-emitting diode ED2, and the fourth light-emitting diode ED4, while a second driving power voltage ELVDD2, having a different value from the first driving power voltage ELVDD1, may be applied to the third light-emitting diode ED3. Further details regarding this configuration will be described later.

FIG. 6 is a plan view illustrating a portion of the display device. For convenience of description, FIG. 6 also shows elements that are overlapped and obscured in a planar view. Referring to FIG. 6, the display device may include the first power line VL1 and the second power line VL2.

In an embodiment of the disclosure, the first driving power line VL1-1 may be electrically connected to the first light-emitting diode ED1, the second light-emitting diode ED2, and the fourth light-emitting diode ED4 to supply the first driving power voltage ELVDD1 (shown in FIG. 2). The second driving power line VL1-2 may be electrically connected to the third light-emitting diode ED3 to supply the second driving power voltage ELVDD2 (shown in FIG. 2). In an embodiment, the second driving power voltage ELVDD2 may have a higher value than the first driving power voltage ELVDD1.

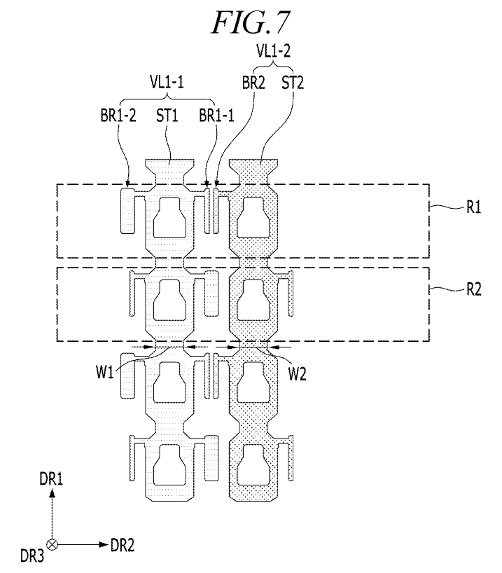

FIG. 7 is a schematic plan view illustrating a portion of the display device. FIG. 7 shows portions of the first driving power line VL1-1 and the second driving power line VL1-2. Referring to FIG. 7, in an embodiment of the disclosure, the first driving power line VL1-1 may include a first stem part ST1, a first sub-branch part BR1-1, and a second sub-branch part BR1-2.

The first stem part ST1 may extend along the first direction DR1. The first sub-branch part BR1-1 may extend from one side of the first stem part ST1 in the second direction DR2, while the second sub-branch part BR1-2 may extend from the opposite side of the first stem part ST1 in the second direction DR2. The first sub-branch part BR1-1 and the second sub-branch part BR1-2 may be iteratively arranged along the first direction DR1.

In an embodiment of the disclosure, the second power line VL2 may include a second stem part ST2 and a second branch part BR2. The second stem part ST2 may extend along the first direction DR1. The second branch part BR2 may extend from one side or the opposite side of the second stem part ST2 in the second direction DR2. The second branch part BR2 may be alternately connected along the first direction DR1 at every row where it extends to one side or the opposite side of the second stem part ST2 in the second direction DR2.

In an embodiment, the first sub-branch part BR1-1, the second sub-branch part BR1-2, and the second branch part BR2 may be arranged next (adjacent) to each other along the second direction DR2 and included within a single row R1 or R2. In an embodiment, the first stem part ST1 may have a first width W1 in the second direction DR2, and the second stem part ST2 may have a second width W2 in the second direction DR2. The first width W1 and the second width W2 may have substantially the same value. In an embodiment, the second branch part BR2 is disposed relatively closer to the first sub-branch part BR1-1 than to the second sub-branch part BR1-2.

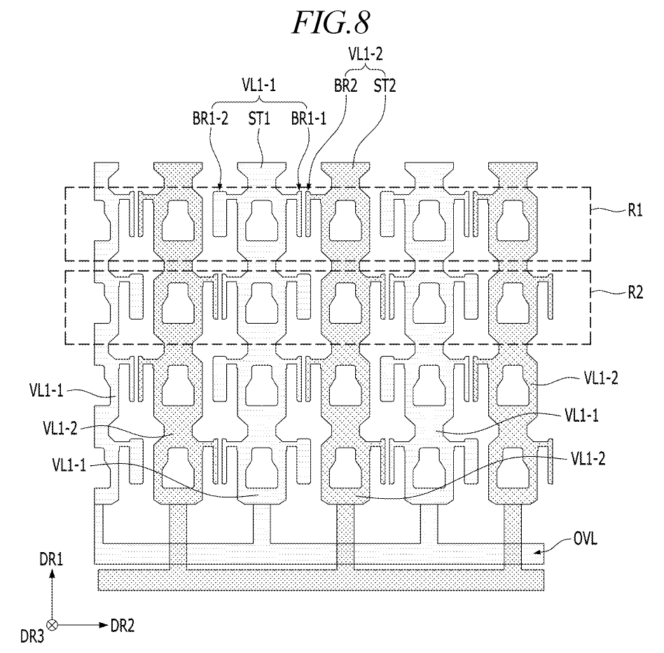

FIG. 8 is a schematic plan view illustrating a portion of a display device. Referring to FIG. 8, the first driving power line VL1-1 and the second driving power line VL1-2 may be alternately arranged along the second direction DR2. The first driving power lines VL1-1 may be connected to each other at one end in the first direction DR1. Similarly, the second driving power lines VL1-2 may be connected to each other at one end in the first direction DR1. In an embodiment, the first driving power lines VL1-1 and the second driving power lines VL1-2 may have an overlapping portion OVL in a planar view but may not contact each other in a cross-sectional view or electrically connected to each other. That is, the first driving power lines VL1-1 and the second driving power lines VL1-2 may be electrically insulated from each other.

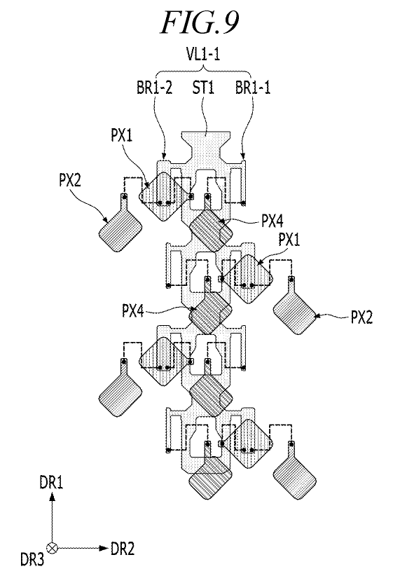

FIG. 9 is a schematic plan view illustrating a portion of the display device. Referring to FIG. 9, the first driving power line VL1-1 may be electrically connected to the first pixel PX1, the second pixel PX2, and the fourth pixel PX4.

In an embodiment, the first driving power line VL1-1 may be electrically connected to the first pixel PX1 and the second pixel PX2 via the second sub-branch part BR1-2. The first driving power line VL1-1 may be electrically connected to the fourth pixel PX4 via the first sub-branch part BR1-1. In an embodiment, the first driving power line VL1-1 may be iteratively connected to the first pixel PX1, the second pixel PX2, and the fourth pixel PX4 along the first direction DR1.

As illustrated in FIG. 9, the first sub-branch part BR1-1 and the second sub-branch part BR1-2 may be alternately arranged along the first direction DR1 at one side of the first driving power line VL1-1 in the second direction DR2. Similarly, the first sub-branch part BR1-1 and the second sub-branch part BR1-2 may be alternately arranged along the first direction DR1 at the opposite side of the first driving power line VL1-1 in the second direction DR2.

The first sub-branch part BR1-1 may be electrically connected to the first pixel PX1 and the second pixel PX2, and the second sub-branch part BR1-2 may be electrically connected to the fourth pixel PX4. Since the unit pixel group PXG is iteratively disposed along the first direction DR1, as previously described, the first driving power line VL1-1 may be repeatedly connected to the first pixel PX1, the second pixel PX2, and the fourth pixel PX4 along the first direction DR1.

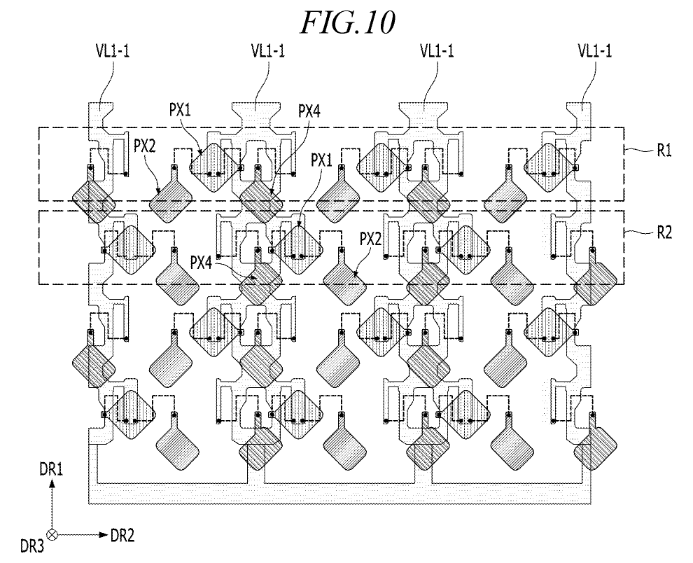

FIG. 10 is a schematic plan view illustrating a portion of the display device. Referring to FIG. 10, in an embodiment of the disclosure, a single first driving power line VL1-1 may be electrically connected to the first pixel PX1, the second pixel PX2, and the fourth pixel PX4 in a first row R1. Similarly, a single first driving power line VL1-1 may be electrically connected to the first pixel PX1, the second pixel PX2, and the fourth pixel PX4 in a second row R2.

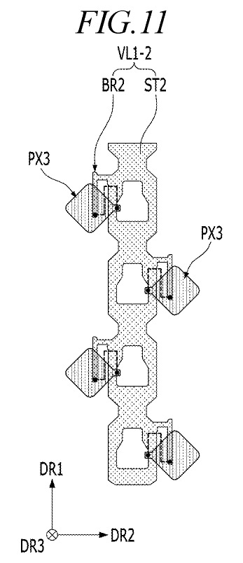

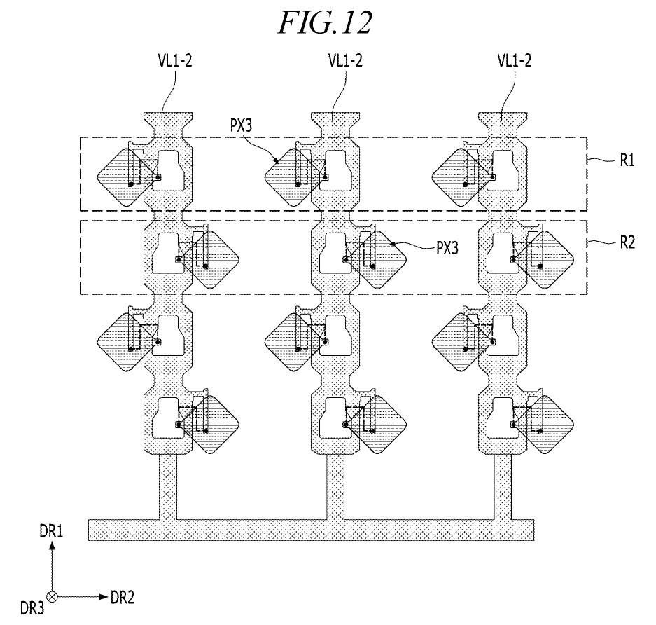

FIG. 11 is a schematic plan view illustrating a portion of the display device. Referring to FIG. 11, the second driving power line VL1-2 may be electrically connected to the third pixel PX3. In an embodiment, the second driving power line VL1-2 may be electrically connected to the third pixel PX3 via the second branch part BR2. In an embodiment, the second driving power line VL1-2 may be repeatedly connected to the third pixel PX3 along the first direction DR1.

As illustrated in FIG. 11, the second branch part BR2 may extend from one side of the second stem part ST2 in the second direction DR2 in the first row R1. Additionally, the second branch part BR2 may extend from the opposite side of the second stem part ST2 in the second direction DR2 in the second row R2. That is, the second branch part BR2 may be alternately arranged on one side and the opposite side of the second stem part ST2 along the first direction DR1.

FIG. 12 is a schematic plan view illustrating a portion of the display device. Referring to FIG. 12, in an embodiment of the disclosure, a single second driving power line VL1-2 may be electrically connected to a single third pixel PX3 in the first row R1. Similarly, a single second driving power line VL1-2 may be electrically connected to a single third pixel PX3 in the second row R2.

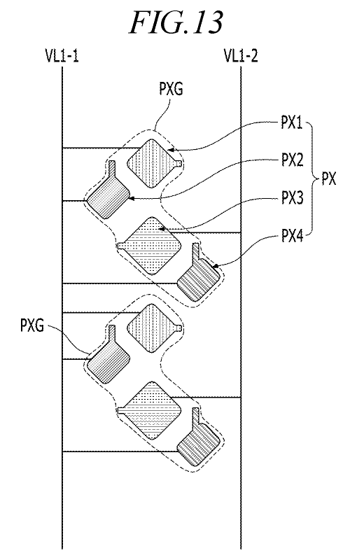

FIG. 13 is a schematic diagram illustrating electrical connections of the pixels. Referring to FIG. 13, in an embodiment, the first driving power line VL1-1 may be electrically connected to the first pixel PX1, the second pixel PX2, and the fourth pixel PX4 within a single unit pixel group PXG. Since the unit pixel group PXG is iteratively disposed along the first direction DRb, the first driving power line VL1-1 may be iteratively connected to the first pixel PX1, the second pixel PX2, and the fourth pixel PX4 along the first direction DR1.

The second driving power line VL1-2 may be electrically connected to the third pixel PX3 within the unit pixel group PXG. The second driving power line VL1-2 may be iteratively connected to the third pixel PX3 along the first direction DR1.

In the display device DD (shown in FIG. 1) according to the disclosure, the first power line VL1 (shown in FIG. 2) configured to apply a power voltage to the light-emitting diodes ED1, ED2, ED3, and ED4 may be any one of the first driving power line VL1-1 and the second driving power line VL1-2. The second driving power line VL1-2 may supply the second driving power voltage ELVDD2, which is higher than the first driving power voltage ELVDD1, to the third light-emitting diode ED3 having a tandem structure, thereby improving the luminous efficiency and reliability of the display device DD.

FIG. 14 is a schematic diagram illustrating electrical connections of the pixels. Referring to FIG. 14, in an embodiment, the first data line DL1 configured to transfer the first data signal may be electrically connected to the second pixel PX2 and the third pixel PX3 within a single unit pixel group PXG. The second data line DL2 configured to transfer the second data signal may be electrically connected to the first pixel PX1 and the fourth pixel PX4 within a single unit pixel group PXG.

Since the unit pixel group PXG is iteratively disposed along the first direction DR1, the first data line DL1 may be alternately connected to the second pixel PX2 and the third pixel PX3 along the first direction DR1, while the second data line DL2 may be alternately connected to the first pixel PX1 and the fourth pixel PX4 along the first direction DR1.

The display device in an embodiment of the disclosure may be applied to various electronic devices. An electronic device in an embodiment may include the above-described display device and may further include additional modules or devices providing functionalities beyond the display device.

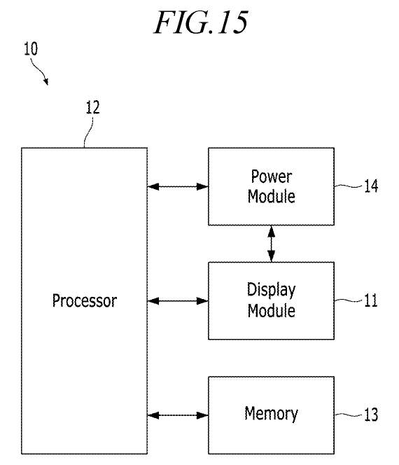

FIG. 15 is a block diagram of an embodiment of an electronic device. Referring to FIG. 15, an electronic device 10 in an embodiment may include a display module 11, a processor 12, a memory 13, and a power module 14.

The processor 12 may include at least one of a central processing unit (“CPU”), an application processor (“AP”), a graphics processing unit (“GPU”), a communication processor (“CP”), an image signal processor (“ISP”), and a controller.

The memory 13 may have data or information desired for the operation of the processor 12 or the display module 11 stored therein. When the processor 12 executes an application stored in the memory 13, video data signals and/or input control signals may be transferred to the display module 11, which may then process the received signals to output visual information through a display screen.

The power module 14 may include a power supply module, such as a power adapter or a battery device, and a power conversion module configured to convert the supplied power and generate the power desired for the operation of the electronic device 10.

At least one of the components of the above-described electronic device 10 may be included in the display device in the embodiments described above. Moreover, some of the individual modules functionally included within a single module may be integrated within the display device, while others may be provided separately from the display device. In an embodiment, the display device may include the display module 11, whereas the processor 12, the memory 13, and the power module 14 may be provided as separate devices within the electronic device 10, rather than being part of the display device, for example.

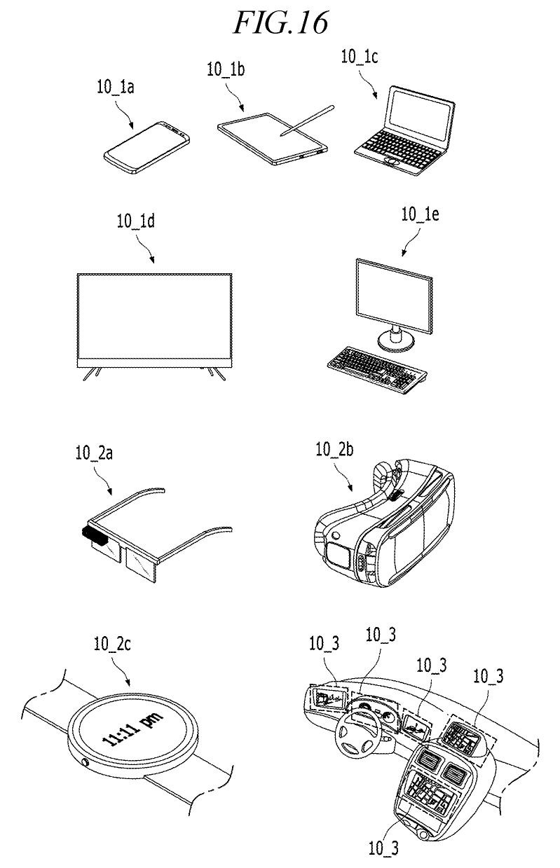

FIG. 16 illustrates embodiments of electronic devices according to the disclosure. Referring to FIG. 16, various electronic devices to which the display device in the embodiments is applied may include not only image display electronic devices such as a smartphone 10_1a, a tablet PC 10_1b, a laptop computer 10_1c, a television (“TV”) 10_1d, and a desktop monitor 10_1e, but also wearable electronic devices including a display module, such as smart glasses 10_2a, a head-mounted display 10_2b, and a smartwatch 10_2c. Furthermore, the display device may also be applied to automotive electronic devices 10_3 including a display module, such as an instrument panel, a center fascia, a dashboard-disposed (e.g., mounted) center information display (“CID”), and a rear-view mirror display.

Hitherto, predetermined preferred embodiments of the disclosure have been described above, but these are merely exemplary and are not intended to limit the disclosure. Those skilled in the art to which the disclosure pertains may make various modifications and changes to the embodiments by adding, changing, deleting, or adding predetermined elements, without departing from the scope of the technical ideas of the disclosure as set forth in the claims, and such modifications and changes should also be regarded as being within the scope of the disclosure.

What is claimed is:

1. A display device comprising:
a substrate; and
first to third light-emitting elements disposed on the substrate, each of the first to third light-emitting elements being configured to emit light in a different wavelength band, each of the first to third light-emitting elements comprising:
a first electrode;
a light-emitting layer; and
a second electrode;
a first driving power line configured to supply a first driving power voltage; and
a second driving power line configured to supply a second driving power voltage,
wherein the third light-emitting element further comprises at least one light-emitting structure layer disposed between the first electrode and the second electrode and comprising at least one light-emitting layer,
wherein the first light-emitting element and the second light-emitting element are electrically connected with the first driving power line,
wherein the third light-emitting element is electrically connected with the second driving power line, and
wherein the second driving power voltage has a value different from a value of the first driving power voltage.

2. The display device of claim 1, wherein the value of the second driving power voltage is greater than the value of the first driving power voltage.

3. The display device of claim 1, wherein the first driving power line and the second driving power line are electrically insulated from each other.

4. The display device of claim 1, further comprising a fourth light-emitting element configured to emit light in a wavelength band substantially identical to a wavelength band of the second light-emitting element,
wherein the fourth light-emitting element is electrically connected to the first driving power line.

5. The display device of claim 4, wherein each of the first to fourth light-emitting elements is provided in plural,
wherein first light-emitting elements and third light-emitting elements are alternately arranged along a first direction, and
wherein second light-emitting elements and fourth light-emitting elements are alternately arranged along the first direction.

6. The display device of claim 5, wherein the first light-emitting elements and the third light-emitting elements are alternately arranged along a second direction intersecting the first direction,
wherein the second light-emitting elements are successively arranged along the second direction, and
wherein the fourth light-emitting elements are successively arranged along the second direction.

7. The display device of claim 4, wherein a first data line configured to transfer a first data signal is electrically connected with the second light-emitting element and the third light-emitting element, and
wherein a second data line next to the first data line and configured to transfer a second data signal is electrically connected with the first light-emitting element and the fourth light-emitting element.

8. The display device of claim 7, wherein each of the first to fourth light-emitting elements is provided in plural,
wherein the first to fourth light-emitting elements form a unit pixel group,
wherein the unit pixel group is iteratively disposed along a first direction,
wherein the first data line and the second data line extend along the first direction,
wherein the first data line is alternately electrically connected with the second light-emitting element and the third light-emitting element along the first direction, and
wherein the second data line is alternately electrically connected to the first light-emitting element and the fourth light-emitting element along a second direction intersecting the first direction.

9. The display device of claim 4, wherein the first driving power line comprises a first stem part extending along a first direction and a first branch part extending from the first stem part,
wherein the second driving power line comprises a second stem part extending along the first direction and a second branch part extending from the second stem part,
wherein the first branch part and the second branch part are arranged side by side along a second direction intersecting the first direction,
wherein the first driving power line is electrically connected with the first light-emitting element, the second light-emitting element, and the fourth light-emitting element through the first branch part, and
wherein the second driving power line is electrically connected with the third light-emitting element through the second branch part.

10. The display device of claim 9, wherein the first branch part comprises:
a first sub-branch part extending from one side of the first stem part in the second direction; and
a second sub-branch part extending from the opposite side of the second stem part in the second direction,
wherein the first driving power line is electrically connected with the first light-emitting element and the second light-emitting element through the second sub-branch part, and
wherein the first driving power line is electrically connected with the fourth light-emitting element through the first sub-branch part.

11. The display device of claim 9, wherein the first branch part comprises a first sub-branch part and a second sub-branch part,
wherein the first sub-branch part and the second sub-branch part from a row in the second direction,
wherein the first sub-branch part and the second sub-branch part are each provided in plural,
wherein the first sub-branch part is disposed on one side of the first stem part in the second direction in a first row,
wherein the second sub-branch part is disposed on the opposite side of the first stem part in the second direction in the first row,
wherein the first sub-branch part is disposed on the opposite side of the first stem part in the second direction in a second row, and
wherein the second sub-branch part is disposed on the one side of the first stem part in the second direction in the second row.

12. The display device of claim 10, wherein the second branch part extends from one side of the second stem part in the second direction, and
wherein the second branch part is disposed relatively closer to the first sub-branch part than to the second sub-branch part.

13. The display device of claim 9, wherein the first stem part and the second stem part have substantially a same width in the second direction.

14. The display device of claim 1, wherein the first driving power line and the second driving power line are each provided in plural,
wherein the first driving power line and the second driving power line each extend along a first direction, and
wherein the first driving power lines and the second driving power lines are alternately arranged along a second direction intersecting the first direction.

15. The display device of claim 14, wherein the first driving power lines are electrically connected to each other, and
wherein the second driving power lines are electrically connected to each other.

16. A display device comprising:
a substrate; and
a first light-emitting element, a second light-emitting element, a third light-emitting element, and a fourth light-emitting element disposed on the substrate, each of the first to fourth light-emitting elements comprising:
a first electrode;
a light-emitting layer; and
a second electrode;
a first driving power line configured to supply a first driving power voltage;
a second driving power line configured to supply a second driving power voltage;
a first data line configured to transfer a first data signal; and
a second data line next to the first data line and configured to transfer a second data signal,
wherein the first light-emitting element, the second light-emitting element, and the third light-emitting element are each configured to emit light in different wavelength bands,
wherein the second light-emitting element and the fourth light-emitting element emit light in substantially a same wavelength band,
wherein the third light-emitting element further comprises at least one light-emitting structure layer disposed between the first electrode and the second electrode and comprising at least one light-emitting layer,
wherein the first light-emitting element, the second light-emitting element, and the fourth light-emitting element are electrically connected with the first driving power line,
wherein the third light-emitting element is electrically connected with the second driving power line,
wherein the first data line is electrically connected with the second light-emitting element and the third light-emitting element, and
wherein the second data line is electrically connected with the first light-emitting element and the fourth light-emitting element.

17. The display device of claim 16, wherein the first driving power line and the second driving power line are electrically insulated from each other, and
wherein the second driving power voltage has a value greater than a value of the first driving power voltage.

18. The display device of claim 16, wherein the first driving power line and the second driving power line are each provided in plural,
wherein the first driving power line and the second driving power line each extend along a first direction, and
wherein the first driving power line and the second driving power line are alternately arranged along a second direction intersecting the first direction.

19. An electronic device comprising:
a substrate; and
first to third light-emitting elements disposed on the substrate, each of the first to third light-emitting elements being configured to emit light in a different wavelength band, each of the first to third light-emitting elements comprising:
a first electrode;
a light-emitting layer; and
a second electrode;
a first driving power line configured to supply a first driving power voltage; and
a second driving power line configured to supply a second driving power voltage,
wherein the third light-emitting element further comprises at least one light-emitting structure layer disposed between the first electrode and the second electrode and comprising at least one light-emitting layer,
wherein the first light-emitting element and the second light-emitting element are electrically connected with the first driving power line,
wherein the third light-emitting element is electrically connected with the second driving power line, and
wherein the second driving power voltage has a value different from a value of the first driving power voltage.

20. The electronic device of claim 19, wherein the value of the second driving power voltage is greater than the value of the first driving power voltage.
